(19) United States
(12) Patent Application Publication
(10) Pub. No.: US 2025/0093446 A1
(43) Pub. Date: Mar. 20, 2025

(54) METHODS AND APPARATUS FOR MOBILE MRI EMPLOYING A PERMANENT MAGNET

(71) Applicant: PMAI LLC, New Haven, CT (US)

(72) Inventors: Baosong WU, New Haven, CT (US); Tianshun ZHANG, New Haven, CT (US)

(21) Appl. No.: 18/858,024

(22) PCT Filed: Mar. 16, 2023
(86) PCT No.: PCT/US2023/064536

§ 371 Date: Oct. 18, 2024

Related U.S. Application Data
(60) Provisional application No. 63/320,410, filed on Mar. 16, 2022.

(51) Int. Cl. G01R 33/389; G01R 33/36; G01R 33/38; G01R 33/383; G01R 33/3875

(52) U.S. Cl. CPC G01R 33/389; G01R 33/3614; G01R 33/365; G01R 33/3806; G01R 33/383; G01R 33/3875

(57) ABSTRACT

Methods and apparatus are provided to implement low-field MRI systems, which may be accessible and mobile in clinic offices and ICU for point-of-care. The low-field MRI systems are enabled by several features. A mobile magnet provides a stable B0 field generated by permanent material. To increase the stability of the B0 field, a monitoring coil and shimming coil are operated in combination. Further, several non-50 Ohm circuit methods are provided for use in the mobile MRI system. Transmit circuits provided include different damping and detuning circuits. In a receive channel, a receive coil array using parallel-tuned circuits is provided to implement a multi-channel receive. Further, decoupling and off-coil detuning strategies are provided.

### FIELD OF THE INVENTION

The invention relates generally to low-field mobile methods and apparatuses for implementing diagnostic imaging. More specifically, the invention relates to brain magnetic resonance imaging devices.

### BACKGROUND

Magnetic resonance imaging (MRI) techniques have been well used in in vivo imaging in the medical field. When human tissue is in a static magnetic field B0, nuclear spins in the tissue are polarized and have a net aligned moment Mz. If the tissue is subjected to a radiofrequency (RF) field B1 at the Larmor frequency in the x-y plane, Mz may be tipped into the x-y plane to produce a net transverse magnetic moment Mt. Then gradient fields (Gx, Gy, and Gz) may be employed to select nuclear spins in certain regions and spatial encoding may be performed to generate spatial information. The signal is emitted by the excited nuclear spins, and this signal may be detected using one or more RF coils and processed to produce images.

To overcome low sensitivity in inductive detection of weakly polarized nuclear spins, the majority of clinical MRI scanners employ superconducting magnets producing high magnetic fields (e.g., operating at 1.5T, or 3T even 7T). For best performance, magnets generally should have inhomogeneities on the order of parts per-million (ppm) over an imaging volume. While increased field strength clearly provides the advantage of higher signal-to-noise ratio (SNR), it also carries the baggage of several practical limitations, including increased magnet size and weight, increased specific absorption rate (SAR, which scales with B0²), increased inhomogeneity in both the static field B0 and applied RF field B1, increased potential for heating of implanted devices, and increased image artifacts around metallic devices.

The use of low-field MRI devices using a permanent magnet(s) may address these problems. Further, the use of permanent magnets may make MRI device mobile-enabled and possible to be used for point of care, such as bedside diagnostics or doctors' office.

Thus, a need exists for systems and methods that address the limitations above. The following disclosure includes an improved mobile MRI system with stable B0 field, employing more efficient methods for pulse transmission and signal reception.

### SUMMARY

Embodiments of the system and method for implementing a mobile MRI device that can be used in clinic diagnostics and human research, such as those needed for brain MRI are disclosed. Certain embodiments disclosed herein include methods for MRI circuits that enable simpler and more efficient transmission and receipt. Certain embodiments disclosed herein also include a method for stabilizing the B0 field,

In embodiments, a method for stabilizing a magnetic field of a mobile MRI device using a permanent magnet is provided. The method includes providing, by the permanent magnet of the mobile MRI device, a main static magnetic field; providing, by a frequency measurement module of the mobile MRI device, a radiofrequency pulse to induce a free induction decay (FID) signal; monitoring, by the frequency measurement module, a phase of the FID signal to determine a frequency of the main static magnetic field; and adjusting, by a compensation module, a frequency of the main static magnetic field.

In embodiments, a system for transmitting an RF field in a mobile MRI device comprising a transmit channel is provided. The transmit channel includes a class-D power amplifier, anti-parallel diodes, one or more circuits configured for detuning or damping, and at least one of a tuned RF coil and an untuned RF coil.

In further embodiments, a mobile MRI device is provided. The mobile MRI device includes a permanent magnet configured to provide a main static magnetic field; and a receive channel. The receive channel includes a parallel-tuned probe, a pre-amplifier; at least one detuned circuit; an impedance transformer; and a signal acquisition device.

### BRIEF DESCRIPTION OF THE FIGURES

FIG. 1 is an overall diagram illustrating a mobile MRI system with the functions of stabilizing field and imaging according to embodiments hereof.

FIG. 2A illustrates an MRI system with permanent magnet and array receive coil according to embodiments hereof.

FIG. 2B illustrates aspects of a receive coil employing a geometry decoupling strategy, according to embodiments hereof.

FIG. 3A illustrates a mobile MRI system including its mechanical assembly, according to embodiments hereof.

FIG. 3B illustrates a mobile MRI system including its mechanical assembly, according to embodiments hereof.

FIG. 4 is a schematic diagram illustrating hardware for a field monitoring channel, according to embodiments hereof.

FIG. 5 is a flowchart illustrating a process of monitoring and compensating magnetic field, according to embodiments hereof.

FIG. 6 is a schematic diagram of a transmit channel using a tuned coil and combined with detuning and damping circuit, according to embodiments hereof.

FIG. 7 illustrates a schematic diagram of the hardware for Class-D RF power amplifier, according to an example embodiment.

FIG. 8 is a schematic of a transmit coil employing parallel-tuned circuit for use with damping and detuning circuit, according to embodiments hereof.

FIG. 9 is a schematic of a transmit coil employing a serial-tuned circuit for use with a damping and detuning circuit, according to embodiments hereof.

FIG. 10 is a schematic diagram of a transmit channel using an untuned coil and combined with a damping circuit, according to embodiments hereof.

FIG. 11 is a schematic of transmit coil employing untuned circuit for use with damping circuit, according to embodiments hereof.

FIG. 12 is an overall schematic diagram of a receive channel with a detuning circuit, according to embodiments hereof.

FIG. 13 is a schematic illustrating a detuning and preamplifier-decoupling strategy in a receive channel, according to embodiments hereof.

FIG. 14 is a graph of an induced current measurements using sniffer loops, according to embodiments hereof.

### DETAILED DESCRIPTION OF THE INVENTION

The present disclosure provides systems, methods, and devices for improving mobile MRI systems. Mobile MRI systems may be easily deployed for point of care, such as in an ICU or doctors' office. The development of mobile MRI devices may have several significant advantages.

One of the advantages in using low field devices is the reduced Lorentz forces, which typically result in a much-reduced acoustic noise level, which is highly desirable for patient studies. Another advantage is that tissue longitudinal relaxation times (T1) decrease with decreasing magnetic field B0 while transverse relaxation times (T2*/T2) increase with decreasing magnetic field B0. Using such low field mobile MRI devices, the shorter T1 and prolonged T2s of tissues may be a benefit for acquisitions with reduced polarized time and long echo trains. Another advantage in using low fields is the possibility of using shorter RF pulses (as no SAR limitations are to be expected), as well as a more homogeneous contrast due to the increased B1 homogeneity. These choices can open up the potential for new applications of techniques, such as fast spin echo (FSE), that may be problematic at high field strength. Thus, mobile MRI devices have many advantages if image quality is acceptable for use in clinic application.

Homogeneity and stability of the static magnetic field B0 are both important for a mobile MRI system using a permanent magnet. The size of the uniform region of a magnet field is defined as the diameter of spherical volume (DSV). Magnet homogeneity is directly related to image quality and various artifacts (e.g., blurring). Another important factor is that inhomogeneity in the B0 field may cause T2* to be reduced, which may be a disadvantage for some sequences, such as gradient-echo sequences (GRE).

It is also important to assure the temperature stability of the B0 field when a permanent magnet is used. The B0 field may change or the homogeneity may worsen when the room temperature changes by even one degree, a change which may be normal in a hospital room with central air.

RF Power amplifiers of the type Class-D have been used in low-frequency NMR/MRI applications and may achieve high efficiencies. This type of RF amplifier also enables a transmit coil using a parallel-tuned circuit, non-resonance circuit, and even a serial-tuned circuit. These circuits may be easier to build and may also change resonance frequency by switching capacitors if needed. On the receive side, using an array based receive coil, an impedance-matched and tuned circuit (50 Ohm) may be used and combined with a preamplifier decoupling technique. Parallel-tuned circuits may have the advantage of an impedance-matched circuit in high signal gain. In addition, large-value inductors with high Q used in a pre-amplifier decoupling circuit may be needed in a low field MRI device. The proposed pre-amplifier decoupling method in this disclosure may use fewer lumped components. Parallel-tuned circuits on coil may also have the benefit in reduced signal loss using fewer lumped components.

The present disclosure includes methods to stabilize magnetic field through use of a frequency measurement module and a compensation module. The ability to stabilize the B0 field is desirable for a permanent-magnet based MRI system to obtain good image quality. The advantages of embodiments of the present disclosure are not limited to mobile MRI systems and may be used to improve field stability in any MRI system.

The present disclosure includes a method using tuned and untuned circuits to simplify a transmit channel of a mobile MRI system. In addition, corresponding methods for damping and detuning are presented herein. The ability of such circuits may reduce the effect of the transmit coil when it is not used.

The present disclosure includes a method using a parallel-tuned array coil combined with a pre-amplifier decoupling technique for a mobile MRI system. In addition, a detuning method using an off-coil circuit is employed to disable receive array coil when not used.

Although described with respect to mobile MRI systems, the features and embodiments discussed herein are not limited to use with such mobile MRI systems.

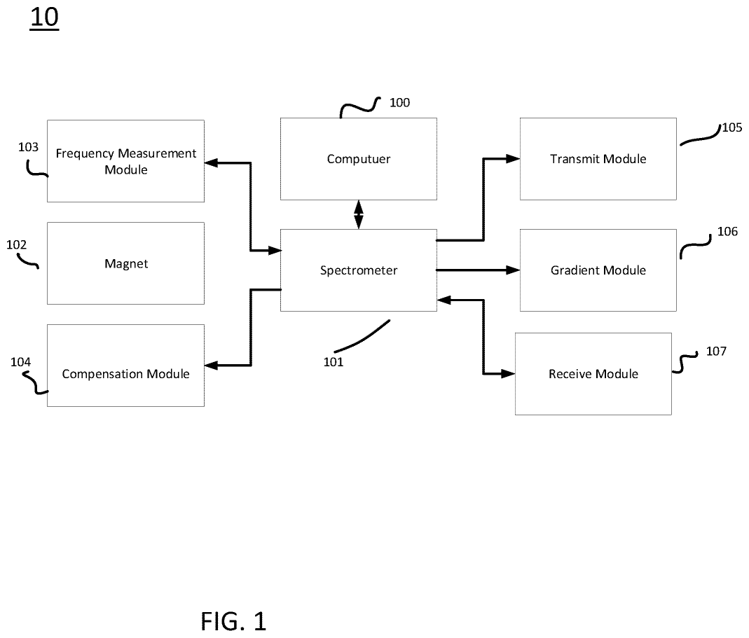

FIG. 1 illustrates an example embodiment of a mobile MRI device 10 based on a permanent magnet configured to provide a main static magnetic field B0. The system includes several modules for implementing two functions: stabilizing the static magnetic field and imaging. A spectrometer 101, functioning as a key component of the mobile MRI device 10, functions to connect these modules together and interface with a computer configured to interpret results. In this example system, a permanent magnet 102 is used to generate a uniform static magnetic field that is stabilized by a frequency measurement module 103 and compensation module 104 (referred to collectively as a monitoring subsystem). The computer 100 is connected to spectrometer 101 and is configured to monitor magnetic field variation measured by the frequency measurement module 103. The field variation measurements of the magnetic field are sent to the computer 100 and analyzed. The computer 100 then controls the spectrometer 101 to adjust the magnetic field by the compensation module.

As shown in FIG. 1, MRI sequence information is sent out from the computer 100 to spectrometer 101, which controls gradient module 106, transmit module 105, and receive module 107, respectively. The transmit module 105 uses an RF field with a short duration to tip nuclear spin magnetizations or focus them together. The gradient module 106, which may include three gradient amplifiers, is configured to select the region of interest spins or do spatial encoding; while the receive module 107 is configured to measure the magnetic field generated by the induced spins and amplify these signals. By combining the functions of the transmit module 105, the gradient module 106, and the receive module 107, the MRI imaging function can be implemented. Raw imaging data may be sent to the computer 100 after acquisition by the spectrometer 101. The raw imaging data may be uploaded to cloud computing service center and/or processed by the computer 100. After processing, the raw image data may be sent back to the computer 100 and displayed, or simply displayed if processing is performed locally. The processing procedure may include denoising algorithms, which are not discussed herein.

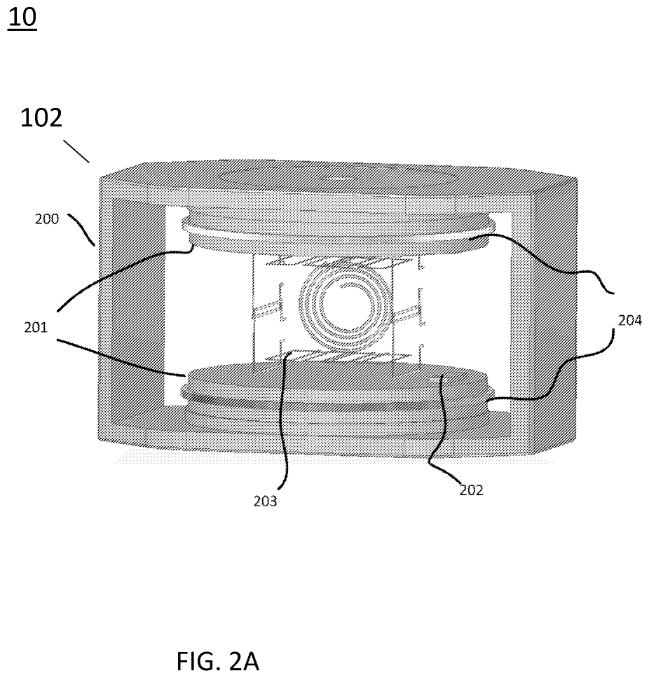

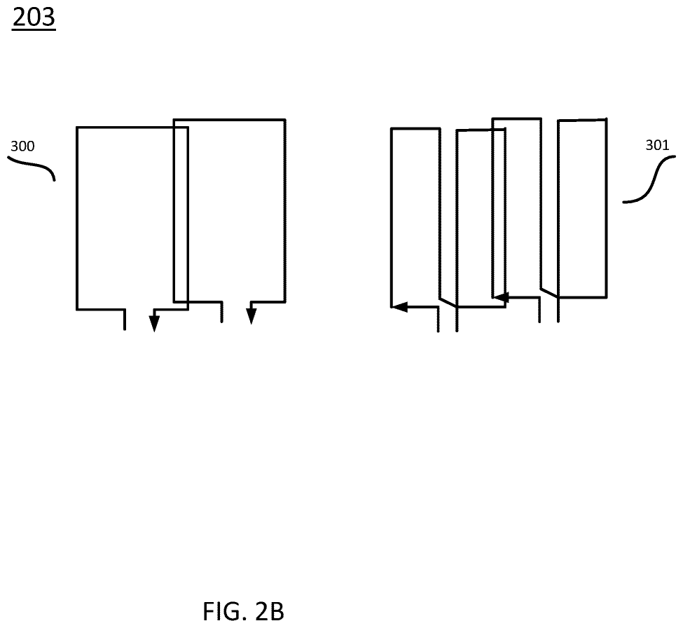

FIG. 2A illustrates an example embodiment of one aspect of a mobile MRI system 10 or device. The magnet 102 includes an iron yolk 200 and magnetic elements 201 (i.e., magnet blocks, passive shimming material and shim ring). Each magnet block contributes to the static magnetic field. The passive shimming material may include small blocks of permanent magnet. It may also include small blocks of metal. The iron yolk 200, using high magnetic permeability material, can provide a magnetic path for a static field, and also reduce the leakage of magnetic flux. The thickness of the iron yolk may be selected to avoid magnetic saturation. For example, the iron yolk 200 with a 35 mm thickness may be used with a 0.1T magnet. A shim ring, also constructed of a high magnetic permeability material, may constrain the magnetic field and ensure a main magnetic field B0 as more uniform over a certain DSV. In embodiments, the magnet 102 may have a main magnetic field with a vertical direction, as illustrated in FIG. 2A.

The magnetic elements 201 may include X/Y/Z gradient coils. Three gradient coils may be connected to the gradient module 106. In accordance with some embodiments, second-order gradient coils (i.e., Z2 gradient coil) may also be included among the magnetic elements 201. The spectrometer 101, in communication with the gradient module 106, may control gradient power amplifiers to amplify a gradient wave and deliver it to corresponding gradient coils. The gradient coils may use offset currents and have a shimming function to make the static magnetic field more homogeneous. The offset current on the gradient coils may vary with magnetic field fluctuations. A tube for water cooling may be provided around the gradient coils. The water may be pumped with a small DC motor. This may ensure that heat from the gradient coils does not affect the permanent magnet. In embodiments, heat isolation materials may be used between the permanent magnet and the gradient coils. The interface 202 is provided for the connection of the gradient coils and water tube.

The compensation module 104 may include a shimming amplifier and a shimming coil 204. The shimming coil 204 may function as a compensation coil to stabilize the static main magnetic field provided by the permanent magnet 102. The spectrometer 101 controls the output current of a shimming amplifier connected to the shimming coil 204, which supplies DC power (<2 W) to the compensation coil 204. In some embodiments, the shimming coil 204 may use several coils to stabilize the static field. In embodiments, the spectrometer 101 may control the shimming coil 204 in conjunction with the shimming function of the gradient coils of the magnetic elements 201 together to ensure stability and homogeneity of the magnetic field B0.

In embodiments, the mobile MRI device 10 may include a transmit coil connected to or associated with the transmit module 105. To generate a uniform B1 field, the transmit coil may be a solenoid coil or saddle coil disposed outside of a receive coil 203.

The receive coil 203 may be an array coil including 9 elements, including, for example, one conical solenoid coil, four figure-8 coils and four surface coils. Other suitable arrangements of the receive coil 203 may also be selected. The coils in the array of the receive coil 203 may be disposed such that the RF field in the sensitivity region is perpendicular to the B0 field in a vertical direction. FIG. 2B illustrates an example of detailed geometry of a surface coil 300 of the receive coil 203 and a figure-8 coil 301 of the receive coil 203. The surface coil 300 and the figure-8 coil 301 may have more than one turn. There may be overlap between neighboring coils of the array of the receive coil 203 to reduce coupling (e.g. geometry decoupling). In addition to geometry decoupling, a pre-amplifier decoupling method may be used in the array of the receive coil 203 as described further below.

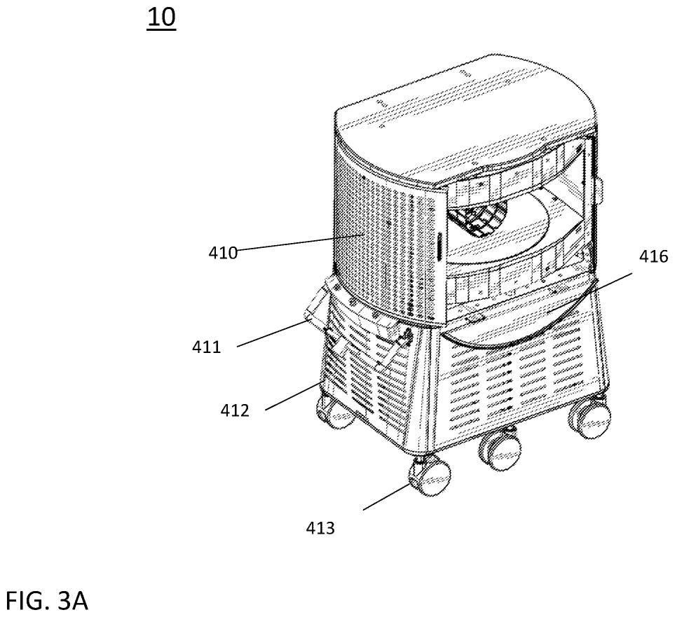

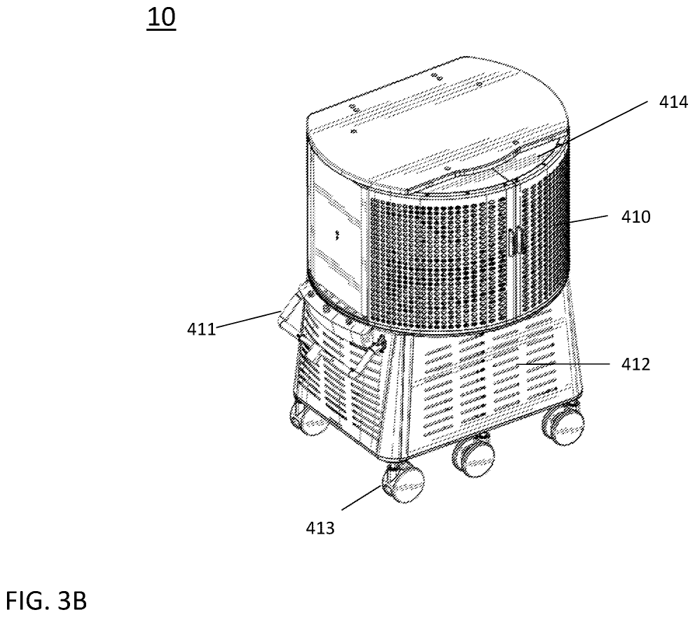

FIG. 3A illustrates the mechanical assembly of a mobile MRI system 10 on wheels. FIG. 3A illustrates the mobile MRI system 10 in an MRI measurement state, where the magnet doors 410 are open. To avoid magnetic metal parts attracted to the magnet, the magnet doors 410 may be closed when the device is in unused state as shown in FIG. 3B. The cover part 414 (shown in FIG. 3B) and support board 416 may also be folded up. The magnet doors 410 may be aluminum, copper, or other suitable material. The cover part 414 and support board 416 may be a plastic or other non-magnetic material. The non-magnetic steel structure 412 may be manufactured by a welding process set on six wheels 413. One or more of wheels 413 may be power assist electric wheels. More or fewer wheels 413 may be used. A handle 411 may be used to move the MRI system 10. The handle 411 may be folded during MRI measurements. The handle 411 may include controls, e.g., triggers, buttons, etc., to control the power assist electric wheels.

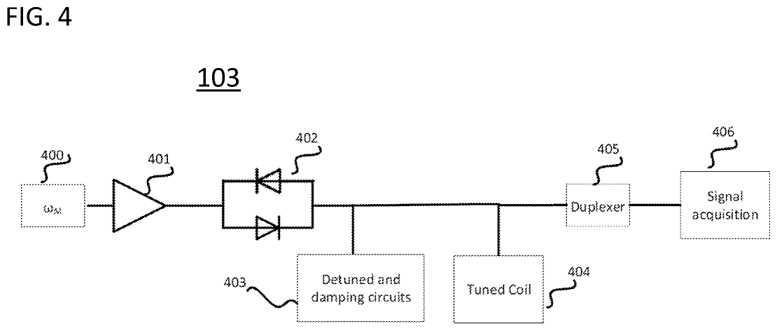

FIG. 4 illustrates an example hardware schematic for the frequency measurement module 103. The frequency measurement module 103 is a small NMR system controlled by the computer 100 and spectrometer 101. RF pulses 400 having angular frequency om are provided by the spectrometer 101 and delivered to a power amplifier 401, which transmits RF power (<10 W) to a tuned RF monitoring coil 404 through a pair of diodes 402. Here the subscript M indicates the monitoring coil 404. The RF monitoring coil 404 may be a solenoid coil or saddle coil and may have a high sensitivity inside. To avoid the effects of a human MRI image during field measurement, a small sample without hydrogen may be inserted into the RF monitoring coil 404 for measuring/monitoring the main static magnetic field B0. The sample may contain, for example, carbon-13 (¹³C) or fluorine-19 (¹⁹F), each of which have a different gyromagnetic ratio from hydrogen (¹H). Thus, the resonance frequency of the samples may be different from hydrogen. For example, hydrogen (¹H) and carbon-13 (¹³C) have resonance frequencies of 42.58 MHz and 10.7 MHz, respectively, at 1 Tesla.

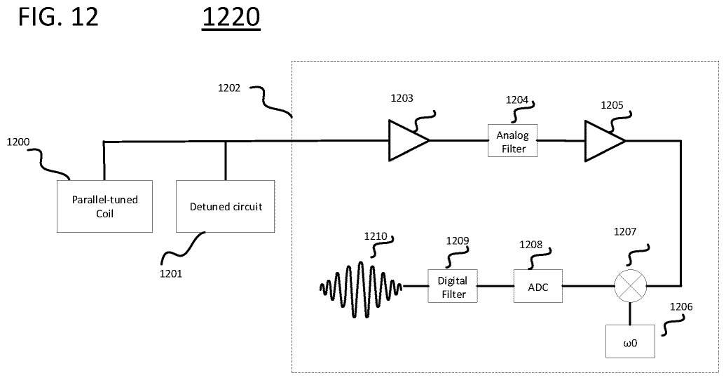

Detuning and damping circuits 403 may be used in the frequency measurement module 103. The detuning and damping circuits 403 are configured to disable the RF monitoring coil 404 and thus to reduce coupling with the transmit coil and the receive coil 203 during MRI imaging. The detuning and damping circuits 403 can reduce the ringdown time of an RF pulse. An example of detuning and damping circuits 403 is provided in more detail below. A duplexer 405, which may, for example, be a π circuit or MOSFET based switch is also employed. The detuning and damping circuits 403 and the duplexer 405 may be in an off-state when the RF monitoring coil 404 transmits pulses. When RF monitoring coil 404 is used as a receive coil, an NMR signal received by the RF monitoring coil 404 runs through the duplexer 405 and is acquired by a signal acquisition circuit 406, described in more detail below with respect to FIG. 12.

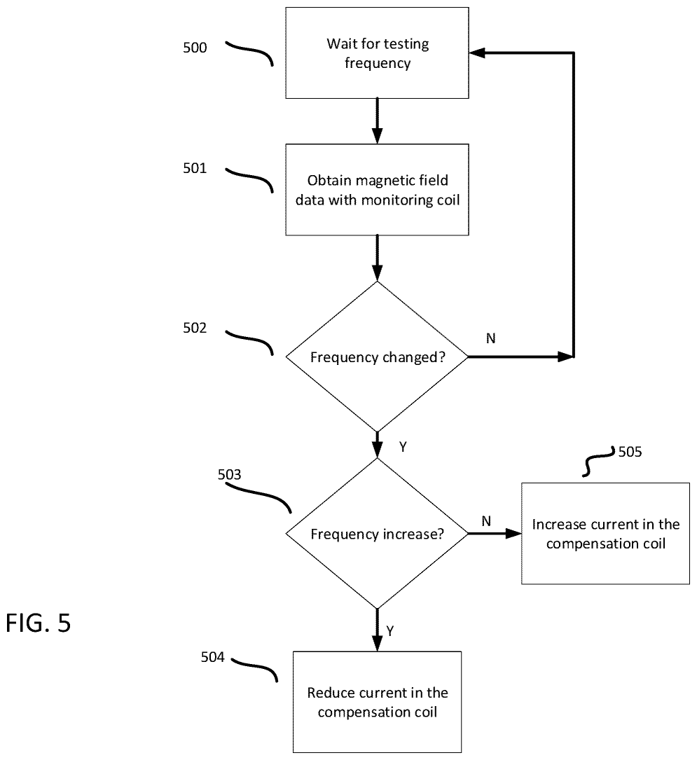

As discussed above, the shimming coil 204 and the frequency measurement module 103 may be combined to stabilize the magnetic field. FIG. 5 is a flowchart illustrating a method of monitoring and compensating the static magnetic field B0. When the mobile MRI system 10 is powered on, the frequency measurement module 103 awaits a command to implement testing the frequency, at step 500. At step 501, the RF monitoring coil 404 of the frequency measurement module 103 is employed to acquire a free induction decay (FID) signal if appropriate commands are provided by the computer 100. Acquiring the FID signal, may include providing, by the frequency measurement module 103 of the mobile MRI device 10, a radiofrequency pulse to induce the FID signal and monitoring or measuring, by the frequency measurement module 103, a phase of the FID signal to determine a frequency of the main static magnetic field.

Fluctuation of the magnetic field B0 will cause fluctuation of the phase in the FID signal. At step 502, the frequency variation in the magnetic field B0 may be evaluated according to measurements of the phase Φ(t) of the FID signal. This may be illustrated using the expression Φ(t)=Φ0+ω*t, where Φ0 is the initial phase. ω (=γ*B) is the linear slope of the phase function. At step 503, this result may be compared with the initial frequency (or linear slope), the fluctuation of magnetic field (ΔB) may be obtained to determine if the frequency has changed. If the frequency has not changed, then the method may return to step 500 and await a command to make a new measurement. If the frequency has changed, then the system may pass control to step 503.

At step 503 it is determined whether the frequency has increased or decreased. If the frequency has increased, then the system acts to reduce current in the shimming coil 204 at step 504. If the frequency has decreased, then the system acts to increase the current in the shimming coil 204. These steps may be repeated to maintain stability of the magnetic field provided by the permanent magnet 102. Imaging may be implemented after the magnetic field is stabilized.

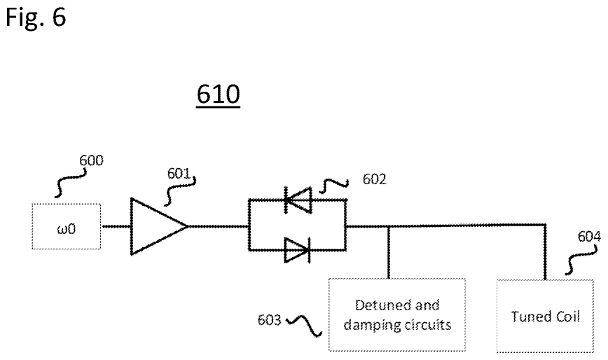

FIG. 6 illustrates a schematic diagram of transmit channel 610 using a transmit coil 604, which also includes detuning and damping circuits 603. The transmit channel 610 in the mobile MRI device delivers an RF pulse 600 with angular frequency Do (received, e.g., from the spectrometer 101 as controlled by the computer 100) to the RF power amplifier 601. The amplified pulse passes through the diodes 602 for application to the RF transmit coil 604, which generates an RF field acting on the nuclear spins.

In embodiments, a class AB power amplifier may be used in high-field human MRI system. In embodiments, a Class-D amplifier may be preferred in low field NMR/MRI devices. A Class-D amplifier may provide better power efficiency and lighter weight than a linear amplifier (i.e., class AB). It may be low energy consumption. These features provide an advantage for use in mobile MRI system, such as the mobile MRI device 10.

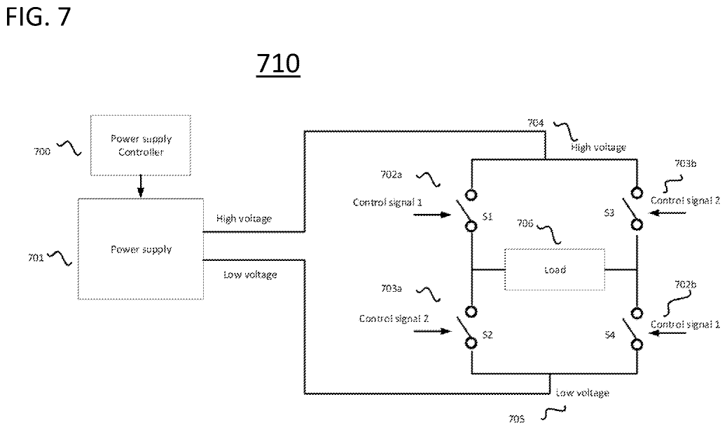

FIG. 7 illustrates a schematic diagram of voltage-mode Class-D power amplifier 710 with a low-impedance output, according to an example embodiment. The amplifier 710 is a switched-mode power amplifiers including switches 702a, 702b, 703a and 703b. The switches 702a, 702b, 703a and 703b may be MOSFET-based switches. Switches 702 (702a and 702b) are controlled by the signal 1, while the switches 703 (703a and 703b) are managed by the signal 2. The signal 1 and signal 2 ensure switches 702 and 703 are not in the closed state at the same time. When switches are closed, high voltage 704 and low voltage 705 are applied on the two terminals of the load 706 (e.g., the transmission coil 604), respectively. These switches may implement frequency modulation of the DC power supply 701, while power supply controller 700 is used for amplitude modulation. The RF power with the amplitude and frequency modulated is applied to the load 706. In accordance with some embodiments, filters may be included to remove the output harmonics of class-D power amplifier.

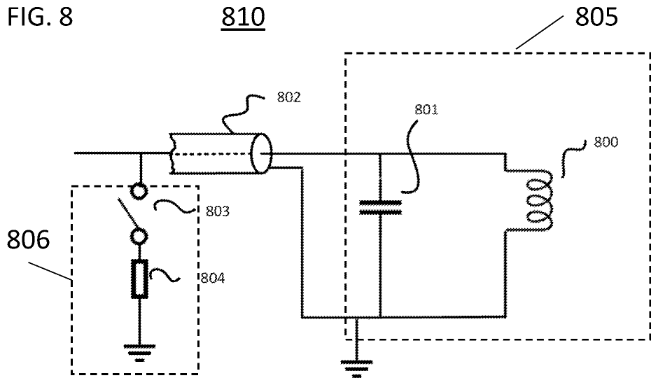

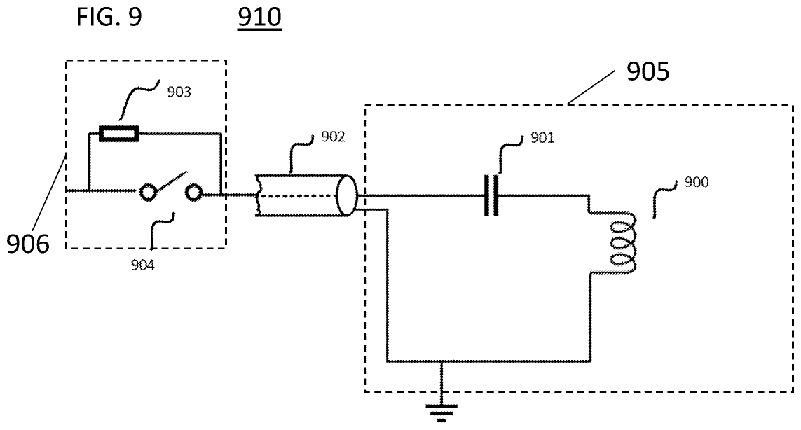

The load 706 in FIG. 7 may be a tuned coil with a parallel circuit or serial circuit, as shown in FIGS. 8 and 9. FIG. 8 illustrates an embodiment of a circuit 810 (representative of the load 706) using a parallel-tuned circuit 805 for use with a damping and detuning circuit 806 (i.e., an example of damping and detuning circuits 403/603). The tuned circuit 805 includes a coil 800 (e.g., transmit coil 604) having an inductance L and a capacitor 801 with capacitance value C in parallel to form the resonance circuit, having a Larmor frequency (ω₀²*L*C=1). The circuit 806, including a switch 803 and a small value resistor 804, may have the function of damping energy and detuning the coil 800. The ringdown time may be reduced when the switch 803 is closed. The circuit 810 may include another switch and a large value resistor disposed in parallel to 803 and 804. Thus the damping energy may be separated into two steps for safety. The larger resistor may be used to damp the main energy while the smaller resistor 804 may be used to damp it further. When the coil 800 is not used, for example, in a receive NMR/MRI signal mode, the circuit 810 may be adjusted to close the switch 803 to detune the coil 800 by shorting it with the small resistor 804. For example, the small resistor may have an impedance value of less than 1 ohm. The circuit components 803 and 804 may be located remotely from the coil 800 via a connection with a coaxial cable 802. The short cable 802 may have a very small impedance and capacitor and its effect may be ignored in low field MRI.

FIG. 9 illustrates a circuit 910 (e.g., representative of the load 706) including a damping/detuning circuit 906 and a serial tuned circuit 905. The coil 900 (e.g., representative of transmission coil 604), having an inductance L′ and the capacitor 901 with capacitance value C′ are disposed in serial to form at resonance circuit at the Larmor frequency (ω₀²*L′*C′=1).

The circuit 910 may normally have a narrow bandwidth when a voltage-mode class-D amplifier is used in FIG. 7. A resistor (not pictured) may be used in serial with the coil 900 for reducing the quality factor (Q) of the coil containing probe. When transmitting RF power to the coil 900, the switch 904 is closed to short the resistor 903. After transmission, the resistor 903 may have a damping function if the switch 904 is open. In addition, except for a period of transmitting power, the circuit 910 may be in an open state due to the anti-parallel diodes 602. The damping/detuning circuit 906, in such a case, may be not needed. In some embodiments, the circuit 910 may be used with a current-mode class-D power amplifier, e.g., as the load 706.

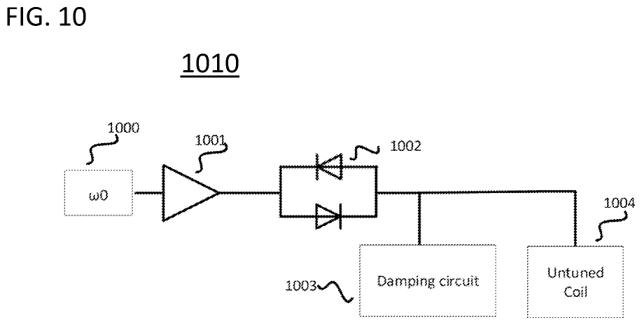

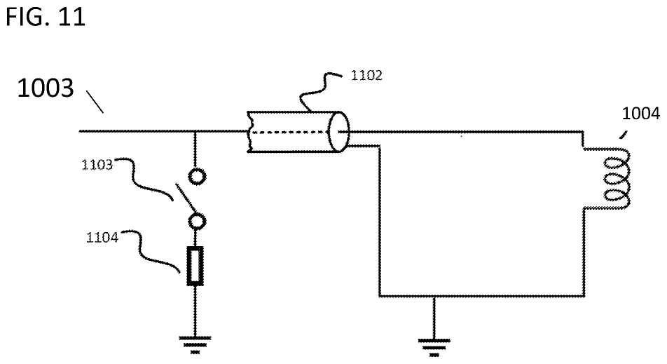

In a further embodiment, the load 706 (shown in FIG. 7) may be an untuned coil 1004 operating as the transmission coil 604. FIG. 10 illustrates an example transmit channel 1010 using an untuned circuit with the damping circuit 1003. As shown in FIG. 10, an RF pulse 1000 at frequency ω₀ is amplified by the amplifier 1001, passed through the diodes 1002 and sent to the untuned coil 1004 operating as the transmission coil. As shown in FIG. 11, in the case of an untuned coil 1004 as transmission coil, it is not expected to use a capacitor. The advantage of employing an untuned coil 1004 is simplicity and flexibility. This arrangement may allow for ultra-broadband and multi-frequency operation in low-field MRI. In such application, a Class-D power amplifier may be arranged closely to the untuned coil 1004 (e.g., transmit coil 604). The damping circuit 1003 includes the switch 1103 and a low impedance resistor 1104. The switch 1103 may be closed to permit resistor 1104 to damp the energy on the coil 1004. The untuned coil 1004 may be blocked by anti-parallel diodes 1002, and detuning the circuit may not be necessary.

In embodiments, the receive coil 203 (see FIG. 2A) may be used to receive an NMR/MRI signal using a parallel imaging technique. The parallel imaging technique can potentially result in a several-fold reduction in imaging time. To function effectively it may be important to minimize the interaction between array elements of the receive coil 203 by use of decoupling techniques. Besides geometric decoupling (e.g., as shown in FIG. 3), there are several decoupling techniques that may be employed, such as inductive decoupling, capacitive decoupling, and pre-amplifier decoupling.

FIG. 12 is a schematic diagram of a receive channel using a preamplifier decoupling method. The receive channel 1220 includes a parallel-tuned probe 1200 having a parallel-tuned coil operating as a receive coil, a detuning circuit 1201, and a signal acquisition circuit 1202. The parallel-tuned probe 1200 having the parallel-tuned coil may be built with one capacitor. The parallel-tuned probe 1200 may have a larger signal gain than a matched and tuned probe, resulting in a lower noise figure (NF) and a higher SNR. Here the detuning circuit 1201 may be used to disable the probe 1200 and protect the signal acquisition circuit 1202 when not in a receive mode.

In a receive mode, the NMR/MRI signal is amplified by the signal amplifier 1203, which may be a low-noise pre-amplifier. The signal amplifier 1203 may include two stages (a first and a second stage). After the signal runs through the analog filter 1204, the signal may be amplified by the signal amplifier 1205 (the third and fourth stage). This is followed by other NMR/MRI components, such as a mixer 1207, an analog to digital converter (ADC) 1208 and a digital filter 1209. The signal mixes with the reference frequency 1206 (Larmor frequency @0) to remove carried frequency. In a low-field NMR/MRI, the mixer 1207 may be replaced by a digital mixer when the ADC 1208 includes an ability to satisfy the Nyquist-Shannon sampling theorem.

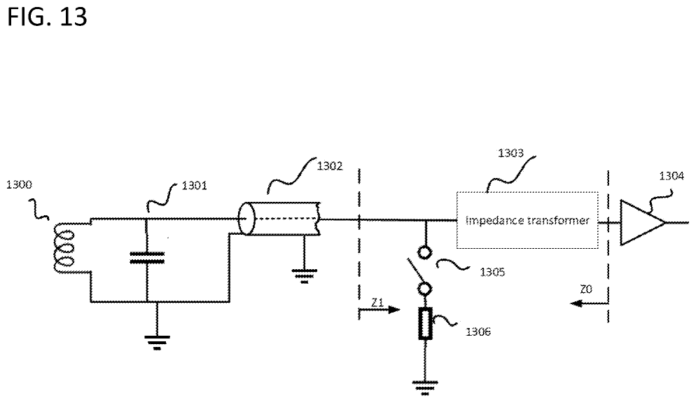

FIG. 13 illustrates a detuning and preamplifier-decoupling strategy for an MRI receive channel (e.g., receive channel 1220). A parallel-tuned coil 1300 is tuned by the capacitor 1301 for use as the probe 1200. The detuning circuit may use a switch 1305 and a small resistor 1306 (approximately equal to 0 Ohms). The switch 1305 may be MOSFET-based or PIN diodes controlled by a DC bias current. An impedance transformer 1303 is used to match the impedance of the probe 1200 to optimal noise impedance of the pre-amplifier 1304. Further, the impedance transformer 1303 may also implement pre-amplifier decoupling. The pre-amplifier 1304 may have a high-impedance input or a low-impedance input. To implement pre-amplifier decoupling, the impedance of Z1 may be approximately a short circuit (looking into the direction of pre-amplifier). In the reverse direction, the impedance of Z0 may be close to optimal noise impedance of the pre-amplifier 1304. In embodiments, several channels for acquiring environmental noise may use the same setup as illustrated in FIG. 13.

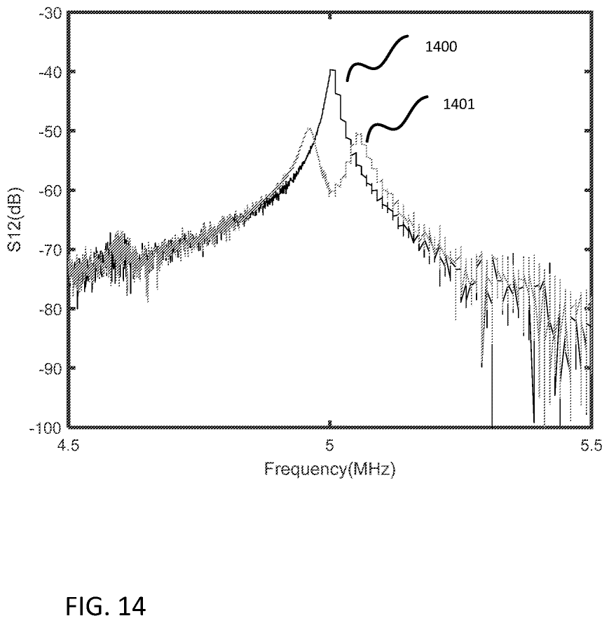

FIG. 14 shows induced current measurements (S21) on the bench, showing a first signal 1401 and a second signal 1400. The first signal 1401 was measured by connecting the circuits (impedance transformer 1303 and pre-amplifier 1304). The parallel-tuned coil 1300 was built at a resonance frequency ˜5 MHz. The second signal 1400 was measured without connecting the impedance transformer 1303 and the pre-amplifier 1304. The pre-amplifier 1340 was an operational amplifier with a high-impedance input. The S21 measurement is proportional to the induced current on the parallel-tuned coil 1300. It can be measured via a pair of decoupled sniffer loops that are brought close to the coil 1300. The difference (ΔS21) in the first signal 1401 and the second signal 1400 indicates that the pre-amplifier decoupling strategy may reduce the coil current by approximately 19 dB.

It will be readily apparent to one of ordinary skill in the relevant arts that other suitable modifications and adaptations to the methods and applications described herein can be made without departing from the scope of any of the embodiments. It is to be understood that while certain embodiments have been illustrated and described herein, the claims are not to be limited to the specific forms or arrangement of parts described and shown. In the specification, there have been disclosed illustrative embodiments and, although specific terms are employed, they are used in a generic and descriptive sense only and not for purposes of limitation. Modifications and variations of the embodiments are possible in light of the above teachings. It is therefore to be understood that the embodiments may be practiced otherwise than as specifically described. All publications, patents and patent applications mentioned in this specification are herein incorporated by reference to the same extent as if each individual publication, patent or patent application was specifically and individually indicated to be incorporated by reference.

1. A method for stabilizing magnetic field of a mobile MRI device using a permanent magnet, the method comprising:
providing, by the permanent magnet of the mobile MRI device, a main static magnetic field;
providing, by a frequency measurement module of the mobile MRI device, a radiofrequency pulse to induce a free induction decay (FID) signal;
monitoring, by the frequency measurement module, a phase of the FID signal to determine a frequency of the main static magnetic field;
adjusting, by a compensation module, a frequency of the main static magnetic field.

2. The method of claim 1, wherein the frequency measurement module includes at least one channel for field monitoring.

3. The method of claim 1, wherein the frequency measurement module includes an NMR probe to monitor the field.

4. The method of claim 1, wherein the frequency measurement module includes ¹³C or ¹⁹F. as an NMR sample.

5. The method of claim 1, wherein the frequency measurement module includes a monitoring coil.

6. The method of claim 1, wherein the compensation module includes at least one channel having a shimming amplifier and a shimming coil, and
wherein adjusting the frequency of the main static magnetic field includes adjusting a current applied to the shimming coil.

7. A system for transmitting an RF field in a mobile MRI device comprising:
a transmit channel comprising:
a class-D power amplifier,
anti-parallel diodes,
one or more circuits configured for detuning or damping, and
at least one of a tuned RF coil and an untuned RF coil.

8. The system of claim 7, wherein
the class-D power amplifier includes a voltage mode class-D power amplifier, the system further comprising:
a parallel-tuned probe;
at least one detuning circuit; and
at least one damping circuit.

9. The system of claim 7,
wherein the at least one of a tuned RF coil and an untuned RF coil is a serially tuned RF coil; and
the transmit channel further comprises a resistor serially connected with the serially tuned RF coil to increase the bandwidth.

10. The system of claim 9, wherein the class-D power amplifier is a current-mode class-D power amplifier.

11. The system of claim 7, wherein the class-D power amplifier is a voltage-mode class-D power amplifier and the at least one of a tuned RF coil and an untuned RF coil is an untuned RF coil and the system further comprises a damping circuit.

12. A mobile MRI device including:
a permanent magnet configured to provide a main static magnetic field; and
a receive channel comprising:
a parallel-tuned probe,
a pre-amplifier;
at least one detuned circuit;
an impedance transformer; and
a signal acquisition device.

13. The mobile MRI device of claim 12, wherein the pre-amplifier includes a high impedance input.

14. The mobile MRI device of claim 12, wherein the pre-amplifier includes a low impedance input.

15. The mobile MRI device of claim 12, wherein the receive channel is configured to acquire noise for noise cancellation.

16. The mobile MRI device of claim 12, further including one or more detuning circuits.
